(19) United States
(12) Patent Application Publication
(10) Pub. No.: US 2023/0163167 A1
(43) Pub. Date: May 25, 2023

(54) SEMICONDUCTOR DEVICE INCLUDING A TRENCH GATE STRUCTURE

(71) Applicant: Infineon Technologies AG, Neubiberg (DE)

(72) Inventors: Michael HELL, Erlangen (DE); Thomas Aichinger, Faak am See (AT); Rudolf Elpelt, Erlangen (DE); Caspar Leendertz, Munchen (DE)

(21) Appl. No.: 17/990,142

(22) Filed: Nov. 18, 2022

(30) Foreign Application Priority Data
Nov. 19, 2021 (DE) 102021130312.5

(51) Int. Cl. H01L 29/06; H01L 29/16; H01L 29/10; H01L 29/78; H01L 21/04; H01L 29/66

(52) U.S. Cl. CPC H01L 29/063; H01L 29/1608; H01L 29/1095; H01L 29/7813; H01L 21/0465; H01L 21/047; H01L 29/66068

(57) ABSTRACT

A semiconductor device is provided. In an example, the semiconductor device includes a trench gate structure in a silicon carbide (SiC) semiconductor body. The semiconductor device includes a source region of a first conductivity type that adjoins the trench gate structure in a first segment. The semiconductor device includes a semiconductor region of a second conductivity type. The semiconductor region includes a first sub-region arranged below the source region in the first segment, and a second sub-region arranged in a second segment that adjoins the first segment. The semiconductor device includes a current spread region of the first conductivity type. The current spread region includes a first sub-region that adjoins the trench gate structure in the first segment at a vertical distance to a first surface of the SiC semiconductor body, and a second sub-region that is spaced from the trench gate structure in the second segment at the vertical distance to the first surface by a lateral distance.

### RELATED APPLICATION

This application claims priority to German Patent Application No. 102021130312.5, filed on Nov. 19, 2021, entitled “SEMICONDUCTOR DEVICE INCLUDING A TRENCH GATE STRUCTURE”, which is incorporated by reference herein in its entirety.

### TECHNICAL FIELD

The present disclosure is related to a semiconductor device, for example to a semiconductor device including a trench gate structure in a silicon carbide (SiC) semiconductor body.

### BACKGROUND

Technology development of new generations of semiconductor devices, e.g. diodes, or insulated gate field effect transistors (IGFETs) such as metal oxide semiconductor field effect transistors (MOSFETs), or insulated gate bipolar transistors (IGBTs), aims at improving electric device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RₒₙxA, may have an impact on other electric device characteristics such as, for example, switching characteristics or short-circuit behavior. Moreover, shrinking of device geometries may be accompanied by challenges for meeting demands on device reliability that may be caused by high electric fields in trench dielectrics, e.g. gate dielectrics.

There is a need for improving electric characteristics of semiconductor devices.

### SUMMARY

An example of the present disclosure relates to a semiconductor device including a trench gate structure in a silicon carbide (SiC) semiconductor body. The semiconductor device includes a source region of a first conductivity type that adjoins the trench gate structure in a first segment. The semiconductor device further includes a semiconductor region of a second conductivity type. The semiconductor region further includes a first sub-region arranged below the source region in the first segment, and a second sub-region arranged in a second segment that adjoins (e.g., directly adjoins) the first segment. The semiconductor device further includes a current spread region of the first conductivity type. The current spread region includes a first sub-region that adjoins (e.g., directly adjoins) the trench gate structure in the first segment at a vertical distance to a first surface of the SiC semiconductor body, and a second sub-region that is spaced from the trench gate structure in the second segment at the vertical distance to the first surface by a lateral distance.

An example of the present disclosure relates to another semiconductor device including a trench gate structure in a SiC semiconductor body. At least a part of the trench gate structure extends along a first lateral direction. The semiconductor device includes a source region of a first conductivity type that adjoins the trench gate structure in a first segment. The semiconductor device further includes a semiconductor region of a second conductivity type. The semiconductor region further includes a first sub-region arranged below the source region in the first segment, and a second sub-region arranged in a second segment that adjoins (e.g., directly adjoins) the first segment. The semiconductor device further includes a current spread region of the first conductivity type. A doping concentration profile defining the current spread region changes, along the first lateral direction, from a first doping concentration level in the first segment to a second doping concentration level in the second segment.

An example of the present disclosure relates to a method of manufacturing a semiconductor device. The method includes forming a trench gate structure in a SiC semiconductor body. The method further includes forming a source region of a first conductivity type that adjoins the trench gate structure in a first segment. The method further includes forming a semiconductor region of a second conductivity type. The semiconductor region includes a first sub-region arranged below the source region in the first segment, and a second sub-region arranged in a second segment that adjoins (e.g., directly adjoins) the first segment. The method further includes forming a current spread region of the first conductivity type, wherein the current spread region includes a first sub-region that adjoins (e.g., directly adjoins) the trench gate structure in the first segment at a vertical distance to a first surface of the SiC semiconductor body, and a second sub-region that is spaced from the trench gate structure in the second segment at the vertical distance to the first surface by a lateral distance.

An example of the present disclosure relates to a method of manufacturing a semiconductor device. The method includes forming a trench gate structure in a SiC semiconductor body. At least a part of the trench gate structure extends along a first lateral direction. The method further includes forming a source region of a first conductivity type that adjoins the trench gate structure in a first segment. The method further includes forming a semiconductor region of a second conductivity type. The semiconductor region includes a first sub-region arranged below the source region in the first segment, and a second sub-region arranged in a second segment that adjoins (e.g., directly adjoins) the first segment. The method further includes forming a current spread region of the first conductivity type, wherein a doping concentration profile defining the current spread region changes, along the first lateral direction, from a first doping concentration level in the first segment to a second doping concentration level in the second segment.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of semiconductor devices and methods of manufacturing a semiconductor device and together with the description serve to explain principles of the embodiments. Further embodiments are described in the following detailed description and the claims.

FIGS. 1A to 1D are schematic top- and cross-sectional views for illustrating process features of an example of a semiconductor device including a current spread region.

FIG. 2 is a schematic cross-sectional view for illustrating exemplary features of the current spread region.

FIG. 3 is a schematic graph for illustrating exemplary features of the current spread region.

FIGS. 4A to 4D, 5A and 5B are schematic top- and cross-sectional views for illustrating process features of other examples of semiconductor devices including a current spread region.

FIGS. 6A to 6D are top views for illustrating exemplary transistor cell designs of semiconductor devices including a current spread region.

FIGS. 7, 8 and 9 are schematic cross-sectional views for illustrating exemplary process features of manufacturing semiconductor devices including a current spread region.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

An example of the present disclosure relates to a semiconductor device including a trench gate structure in a SiC semiconductor body. At least a part of the trench gate structure may extend along a first lateral direction. The semiconductor device may include a source region of a first conductivity type that adjoins the trench gate structure in a first segment along the first lateral direction. The semiconductor device may further include a semiconductor region of a second conductivity type. The semiconductor region may further include a first sub-region arranged below the source region in the first segment, and a second sub-region arranged in a second segment that adjoins (e.g., directly adjoins) the first segment along the first lateral direction. The semiconductor device may further include a current spread region of the first conductivity type. The current spread region may include a first sub-region that adjoins (e.g., directly adjoins) the trench gate structure in the first segment at a vertical distance to a first surface of the SiC semiconductor body, and a second sub-region that is spaced from the trench gate structure in the second segment at the vertical distance to the first surface by a lateral distance.

The semiconductor device may be an integrated circuit, or a discrete semiconductor device or a semiconductor module, for example. The semiconductor device may be or may include a power semiconductor device, e.g. a vertical power semiconductor device having a load current flow between a first surface and a second surface opposite to the first surface. The semiconductor device may be or may include a power semiconductor insulated gate field effect transistor (IGFET), e.g. a power semiconductor metal oxide semiconductor field effect transistor (MOSFET), or a power semiconductor insulated gate bipolar transistor (IGBT), or a diode, or a junction field effect transistor (JFET). The power semiconductor device may be configured to conduct currents of more than 1 ampere (A) or more than 10 A or more than 30 A or more than 50 A or more than 75 A or even more than 100 A, and may be further configured to block voltages between load electrodes, e.g. between emitter and collector of an IGBT, or between drain and source of a MOSFET, in the range of several hundreds of up to several thousands of volts, e.g. 400 volts (V), 650V, 1.2 kilovolts (kV), 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

For example, the semiconductor body may be or may include a crystalline SiC semiconductor material, e.g. a crystalline SiC semiconductor substrate and/or crystalline epitaxial SiC layers. For example, the crystalline SiC semiconductor material may have a hexagonal polytype, e.g., 4H or 6H. The semiconductor body may be homogeneously doped or may include differently doped SiC layer portions, e.g., with a doping concentration ranging from 1×10¹⁴ centimeters⁻³ (cm⁻³) to 1×10¹⁷ cm⁻³. For example, the semiconductor body may include, i.e. as differently doped SiC layer portions, a substantially homogeneously doped SiC semiconductor substrate and/or an epitaxial layer or multiple epitaxial layers, e.g. including a buffer layer, on the SiC semiconductor substrate. For example, the semiconductor body may include one or more layers from another material with a melting point close to or higher than crystalline silicon carbide or at least with a melting point exceeding the typical temperatures used for the processing of SiC wafers or substrates. For example, the layers from another material may be embedded in the crystalline SiC semiconductor material.

For example, the trench gate structure may include a gate dielectric and a gate electrode. The gate dielectric may include one or more dielectric material(s), e.g. oxide (for example, silicon dioxide (SiO₂)) such as thermal oxide or deposited oxide, nitride, high- or low-k dielectrics. The gate electrode may include one or more conductive material(s), e.g. metal, metal alloys, highly doped semiconductor material (e.g., semiconductor material doped with higher than a threshold amount of dopants) such as highly doped polycrystalline silicon (e.g., polycrystalline silicon doped with higher than a threshold amount of dopants). The gate dielectric may separate the gate electrode and a channel region. A gate signal applied between the gate electrode and the body region may control the distribution of mobile charge carriers in a channel region by field effect, for example.

In case of a tapered trench gate structure, the channel region may also have a lateral extent. The channel length may be slightly larger than the vertical extent of the channel region in case of a small taper angle of the trench gate structure. The taper angle of the trench gate structure may be caused by process technology, e.g. aspect ratio of trench etch processes, and may also be used for maximizing the charge carrier mobility in the channel region which depends from the direction along which channel current flows. Another example for a tapered trench gate structure is a V-shaped trench gate structure.

For example, the trench gate structure may be stripe-shaped and the first lateral direction may be a longitudinal direction of the stripe-shaped trench gate structure, for example. The trench gate structure may also have another layout or geometry in a plan view, e.g. hexagonal, square, circular, elliptic.

For example, the first segment along the first lateral direction may be a segment or part of a mesa region that is laterally confined by the trench gate structure on one side. The source region of the first conductivity type may be a doped region in the mesa region, for example.

For example, the first sub-region of the semiconductor region may be a body region. For example, a vertical extent of a channel region of the semiconductor device may be defined by a vertical extent of the first sub-region at an interface between the first sub-region and the trench gate structure.

For example, the second sub-region of the semiconductor region may be a shielding region or a body contact region. The second sub-region of the semiconductor region may extend deeper into the semiconductor body than the first sub-region. The second sub-region may also extend below a bottom side of the trench gate structure. The second sub-region may also cover at least part of the bottom side of trench gate structure, or may cover at least part of a bottom side of a second trench gate structure laterally confining the mesa region on another side. The second sub-region may also adjoin a surface of the semiconductor body, e.g. a first surface or front surface or top surface, and may be electrically connected to a load electrode, e.g. a source electrode of a MOSFET, or an emitter electrode of an IGBT. For example, the second sub-region may electrically couple the body region to the load electrode. Therefore, the second sub-region may be configured as a body contact region. Moreover, the second sub-region may also be configured as a shielding region in a lower part, wherein the shielding region is configured to shield a gate dielectric of the trench gate structure from high electric fields (e.g., electric fields higher than a threshold electric field) when a high blocking voltage (e.g., a blocking voltage higher than a threshold blocking voltage) is applied to the semiconductor device during operation. A vertical doping concentration profile of dopants of the second conductivity type along a depth section corresponding to the vertical extent of the first sub-region of the semiconductor region may differ from a vertical doping concentration profile of the second sub-region of the semiconductor region along the depth section, wherein both profiles may be determined at a same lateral distance to the trench gate structure.

For example, the first sub-region of the current spread region may define a channel end at an interface, e.g. pn junction, with the first sub-region of the semiconductor region, e.g. a body region, at the trench gate structure or close to (e.g., within a threshold distance of) the trench gate structure. The first sub-region of the current spread region may be arranged between the first sub-region of the semiconductor region, e.g. a body region, and a drift region of the semiconductor device. An average doping concentration of the first sub-region of the current spread region may be larger than a doping concentration of a part of the drift region adjoining the first sub-region of the current spread region. At a vertical level of a bottom side of the trench gate structure, a first section of a pn junction between the first sub-region of the current spread sheet and the semiconductor region may turn into a second section of the pn junction between the second sub-region of the current spread sheet and the semiconductor region. The second section of the pn junction may extend along the first lateral direction, e.g. a longitudinal direction of a stripe-shaped trench gate structure. The distance between the second sub-region of the current spread region and the trench gate structure may be a lateral distance along a second lateral direction that is perpendicular to the first lateral direction. For example, the second lateral direction may be a direction along a width of the mesa region including the semiconductor region. The distance may be smaller than half of the mesa width, or may be smaller than 40% of the mesa width, or may be smaller than 30% of the mesa width, or may even be smaller than 20% of the mesa width, for example.

By replacing the source region in the second segment with the second sub-region of opposite conductivity type, alternating n-doped and p-doped regions may be arranged at the first surface, e.g. top or front surface, of the semiconductor body. This design may allow for a flexible tuning of a channel width from a ratio larger and smaller than 1 compared to a design having uninterrupted n-stripes as source region. The flexible tuning may be achieved by adjusting a ratio between a first extent of the source region along the first lateral direction and a second extent of the second sub-region of the semiconductor region along the first lateral direction.

Provision of the first and second sub-regions of the current spread region may allow for a reduction of the area-specific on-state resistance, RₒₙxA, which reduces static losses, while the channel width remains unchanged. For example, the second sub-region of the current spread region may improve spreading of a channel current along the longitudinal direction of the mesa region. Moreover, the saturation current may only hardly change (e.g., the saturation current may change by less than a threshold amount) and the same short-circuit time can be expected when introducing the second sub-region of the current spread region. Moreover, the gate-to-drain capacitance/gate-to-source capacitance ratio (CGD/CGS) may not be affected or may only negligibly be affected by introducing the second sub-region of the current spread region. This may be due to an unchanged open trench area, i.e. the area in contact with semiconductor regions of the first conductivity type.

For example, a doping concentration profile defining the current spread region may change, along the first lateral direction, from a first doping concentration level in the first segment to a second doping concentration level in the second segment.

Details with respect to structure, or function, or technical benefit of features described above likewise apply to the examples below and vice versa.

An example of the present disclosure relates to a semiconductor device including a trench gate structure in a SiC semiconductor body. At least a part of the trench gate structure may extend along a first lateral direction. The semiconductor device may include a source region of a first conductivity type that adjoins the trench gate structure in a first segment along the first lateral direction. The semiconductor device may further include a semiconductor region of a second conductivity type. The semiconductor region may further include a first sub-region arranged below the source region in the first segment, and a second sub-region arranged in a second segment that adjoins (e.g., directly adjoins) the first segment along the first lateral direction. The semiconductor device may further include a current spread region of the first conductivity type. A doping concentration profile defining the current spread region may change, along the first lateral direction, from a first doping concentration level in the first segment to a second doping concentration level in the second segment.

The first and second sub-regions of the semiconductor region may be arranged alternately along the first lateral direction, for example. Likewise, the first and second sub-regions of the current spread region may be arranged alternately along the first lateral direction, for example. The trench gate structure, the source region, the semiconductor region, and the current spread region may be part of a transistor cell, e.g. a stripe-shaped transistor cell. The semiconductor device may include a plurality of transistor cells in a transistor cell array. The transistor cells may be arranged regularly, e.g. as a plurality of parallel stripe-shaped transistor cells. Transistor cell designs other than stripe-shape may also be used, e.g. hexagonal, square, circular, elliptic.

For example, the second sub-region of the semiconductor region may be arranged between the second sub-region of the current spread region and the trench gate structure. A first section of a pn junction may be located between the first sub-region of the current spread region and the second sub-region of the semiconductor region. The first section of the pn junction may extend along the second lateral direction that is perpendicular to the first lateral direction. A second section of the pn junction may be located between the second sub-region of the current spread region and the second sub-region of the semiconductor region. The second section of the pn junction may extend along the first lateral direction, e.g. longitudinal direction of a stripe-shaped trench gate structure.

For example, a vertical distance of a pn junction between the semiconductor region and the current spread region to a first surface of the SiC semiconductor body may change, along the first lateral direction, from a first vertical distance in the first segment to a second vertical distance in the second segment. In some examples, the first vertical distance may be larger than the second vertical distance. In some other examples, the first vertical distance may be smaller than the second vertical distance. For example, the first and second vertical distances may differ from one another by less 500 nm, or by less than 300 nm, or by less than 100 nm.

For example, a vertical concentration profile of dopants defining the first sub-region of the semiconductor region may differ from a vertical concentration profile of dopants defining the second sub-region of the semiconductor region. For example, a vertical doping concentration profile of dopants of the second conductivity type along a depth section corresponding to the vertical extent of the first sub-region of the semiconductor region may differ from a vertical doping concentration profile of the second sub-region of the semiconductor region along the depth section, wherein both profiles may be determined at a same lateral distance to the trench gate structure. For example, the vertical doping concentration profile of dopants of the second conductivity type along a depth section that corresponds to the vertical extent of the first sub-region of the semiconductor region may be, partially (e.g., predominantly) or completely, smaller than a vertical doping concentration profile of the second sub-region of the semiconductor body along the depth section, wherein both profiles may be determined at a same lateral distance to the trench gate structure. For example, the vertical doping concentration profile of dopants of the second conductivity type of the second sub-region of the semiconductor region may extend deeper into the SiC semiconductor body than the vertical doping concentration profile of the first sub-region of the semiconductor body.

For example, the doping concentration profile defining the current spread region may alternate, along the first lateral direction, between the first doping concentration level in the first segment and the second doping concentration level in the second segment. For example, the second doping concentration level may be larger than the first doping concentration level. For example, the second doping concentration level may be at most a factor of ten larger than the first doping concentration level (e.g., the second doping concentration level may be at most a first value, wherein the first value is equal to a product of 10 and the first doping concentration level). The relation may hold with respect to a vertical level within the SiC semiconductor body where the first sub-region and the second sub-region of the current spread region are present.

For example, a vertical distance of the pn junction between the semiconductor region and the current spread region to the first surface may vary within the second segment. For example, the pn junction may include a step-shape along the second lateral direction that may be a lateral direction perpendicular to a longitudinal direction of the trench gate structure.

Details with respect to structure, or function, or technical benefit of features described above with respect to a semiconductor device likewise apply to the exemplary methods described herein. Processing the SiC semiconductor body may comprise one or more additional features corresponding to one or more aspects mentioned in connection with the proposed concept or one or more examples described above or below.

An example of the present disclosure relates to a method of manufacturing a semiconductor device. The method may include forming a trench gate structure in a SiC semiconductor body, wherein at least a part of the trench gate structure extends along a first lateral direction. The method may further include forming a source region of a first conductivity type that adjoins the trench gate structure in a first segment along the first lateral direction. The method may further include forming a semiconductor region of a second conductivity type, wherein the semiconductor region includes a first sub-region arranged below the source region in the first segment, and a second sub-region arranged in a second segment that adjoins (e.g., directly adjoins) the first segment along the first lateral direction. The method may further include forming a current spread region of the first conductivity type, wherein the current spread region includes a first sub-region that adjoins (e.g., directly adjoins) the trench gate structure in the first segment, and a second sub-region that is spaced from the trench gate structure in the second segment by a distance.

An example of the present disclosure relates to a method of manufacturing a semiconductor device. The method may include forming a trench gate structure in a SiC semiconductor body, wherein at least a part of the trench gate structure extends along a first lateral direction. The method may further include forming a source region of a first conductivity type that adjoins the trench gate structure in a first segment along the first lateral direction. The method may further include forming a semiconductor region of a second conductivity type, wherein the semiconductor region includes a first sub-region arranged below the source region in the first segment, and a second sub-region arranged in a second segment that adjoins (e.g., directly adjoins) the first segment along the first lateral direction. The method may further include forming a current spread region of the first conductivity type, wherein a doping concentration profile defining the current spread region changes, along the first lateral direction, from a first doping concentration level in the first segment to a second doping concentration level in the second segment.

Apart from the doped regions described above, additional doped regions may be formed in the SiC semiconductor body. For example, field stop region(s), a collector or rear side emitter region of an IGBT, or a drain region of a MOSFET may be formed, e.g. via processing the second surface of the SiC semiconductor body. Alternatively and/or additionally, wafer splitting process(es) and/or wafer thinning techniques may be applied. Moreover, processing the SiC semiconductor body at the first surface may include forming a wiring area over the SiC semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric may be arranged. Contact plug(s) or contact line(s) may be formed in openings in the interlayer dielectric to electrically connect parts, e.g. metal lines or contact areas, of different wiring levels to one another.

For example, forming the second sub-region of the current spread region may include at least one ion implantation process using a first ion implantation mask over a processing surface, e.g. the first or top surface, and forming the second sub-region of the semiconductor region may include at least one ion implantation process using a second ion implantation mask over the processing surface that differs from the first ion implantation mask. Forming the second sub-region of the semiconductor region may include 1, 2, 3, 4, or even more ion implantation processes. The ion implantation processes may differ with respect to ion implantation energy, and/or ion implantation dose, and/or ion implantation doping species or element, and/or ion implantation tilt angle.

For example, the method may further comprise, after the at least one ion implantation process using the first ion implantation mask, and after the at least one ion implantation process using the second ion implantation mask over the processing surface, forming a semiconductor layer over the processing surface. Forming the trench gate structure may include forming a trench into or through the semiconductor layer. For example, a bottom side of the trench may end in the second sub-region of the semiconductor region.

For example, forming the second sub-region of the semiconductor region may include at least one ion implantation process using an ion implantation mask. Forming the second sub-region of the current spread region may include at least one ion implantation process using the ion implantation mask for forming the second sub-region of the semiconductor region. For example, an ion implantation tilt angle for forming the second sub-region of the semiconductor region may differ from an ion implantation tilt angle for forming the second sub-region of the current spread region. For example, an ion implantation tilt angle of the ion implantation process for forming the second sub-region of the semiconductor region may be larger than an ion implantation tilt angle of the ion implantation process for forming the second sub-region of the current spread region.

The aspects and features mentioned and described together with one or more of the previously described examples and figures, may as well be combined with one or more of the other examples in order to replace a like feature of the other example or in order to additionally introduce the feature to the other example.

It will be appreciated that while the method described above and below as a series of acts or events, the described ordering of such acts or events are not to be interpreted in a limiting sense. Rather, some acts may occur in different orders and/or concurrently with other acts or events apart from those described above and below.

Functional and structural details described with respect to the examples above shall likewise apply to the examples illustrated in the figures and described further below.

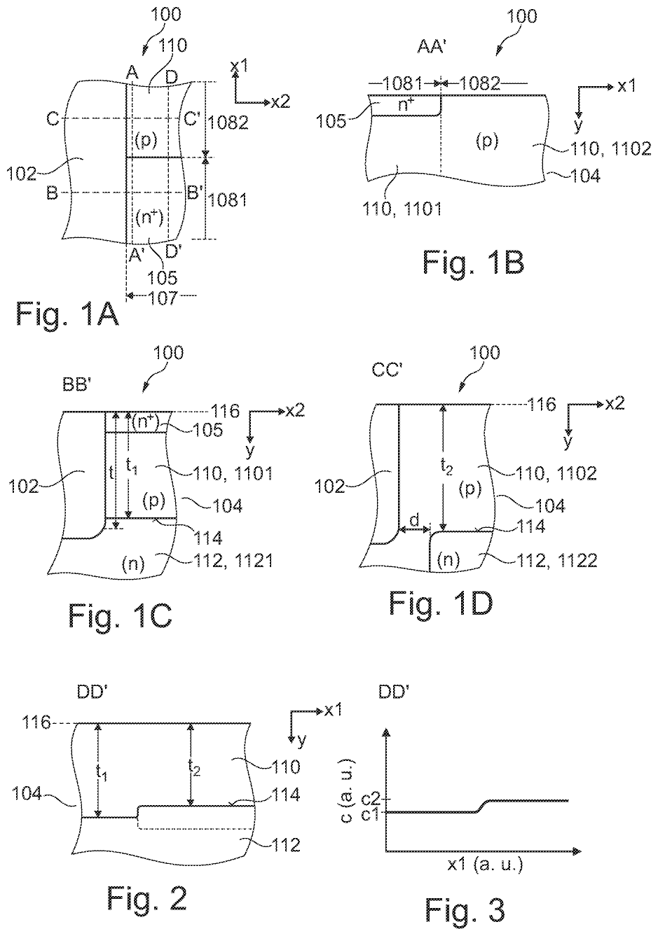

The schematic top view of FIG. 1A and the cross-sectional views of FIGS. 1B to 1D illustrate an example of a semiconductor device 100.

Referring to the schematic top view of FIG. 1A, the semiconductor device 100 includes a trench gate structure 102 in a SiC semiconductor body 104. At least a part of the trench gate structure 102 extends along a first lateral direction x1. For example, the trench gate structure 102 may be stripe-shaped along the first lateral direction x1. The semiconductor device 100 includes an n⁺-doped source region 105 that adjoins the trench gate structure 102 in a first segment 1081 along the first lateral direction x1. The semiconductor device 100 includes a p-doped semiconductor region 110 in a second segment 1082 along the first lateral direction x1. The p-doped semiconductor region 110 adjoins the trench gate structure 102 and adjoins the n⁺-doped source region 105. The p-doped region 110 and the source region 105 are formed in a mesa region 107 of the SiC semiconductor body 104. The mesa region 107 extends in parallel to the trench gate structure 102 along the first lateral direction x1.

The view of FIG. 1B represents a schematic cross-section along line AA′ of FIG. 1A. The semiconductor region 110 includes a first sub-region 1101, e.g. body region, arranged below the source region 105 in the first segment 1081. Further, the semiconductor region 110 includes a second sub-region 1102 arranged in the second segment 1082 that adjoins (e.g., directly adjoins) the first segment 1081 along the first lateral direction x1.

The view of FIG. 10 represents a schematic cross-section along line BB′ of FIG. 1A. The semiconductor region 110 includes an n-doped current spread region 112. The current spread region 112 includes a first sub-region 1121 that adjoins (e.g., directly adjoins) the trench gate structure 102 in the first segment 1081. A pn junction 114 is formed between the first sub-region 1121 of the current spread region 112 and the first sub-region of the semiconductor region 110.

The view of FIG. 1D represents a schematic cross-section along line CC′ of FIG. 1A. The current spread region 112 of the semiconductor device 100 includes a second sub-region 1122 that is spaced from the trench gate structure 102 in the second segment 1082 by a distance d. For example, the distance d may be a lateral distance along the second lateral direction x2.

The view of FIG. 2 represents a schematic cross-section along line DD′ of FIG. 1A. The cross-section is simplified in that it merely illustrates a pn junction 114 between the p-doped semiconductor region 110 and the current spread region 112. In the example illustrated in FIG. 2, a vertical distance of the pn junction 114 between the semiconductor region 110 and the current spread region 112 to a first surface 116 of the SiC semiconductor body 104 changes, along the first lateral direction x1, from a first vertical distance t1 in the first segment 1081 (see also FIG. 10) to a second vertical distance t2 in the second segment 1082 (see also FIG. 1D). In the example of FIG. 2, the first vertical distance t1 is larger than the second vertical distance t2. In other examples, the first vertical distance t1 may be smaller than the second vertical distance t2, or may even be equal to the second vertical distance t2. By adjusting the vertical distances, the current spreading of a channel current may be optimized.

The view of FIG. 3 is a schematic graph illustrating an example of a doping concentration profile along the first lateral direction x1 in the current spread region 112. The doping concentration profile c defining the current spread region 112 changes, along the first lateral direction x1, from a first doping concentration level c1 in the first segment 1081 (see also FIG. 10) to a second doping concentration level c2 in the second segment 1082. In the example of FIG. 3, the first doping concentration level c1 is smaller than the second doping concentration level c2. In other examples, the first doping concentration level c1 may be larger than the second doping concentration level c2, or may even be equal to the second doping concentration level c2. By adjusting the doping concentration levels, the current spreading of a channel current may be optimized.

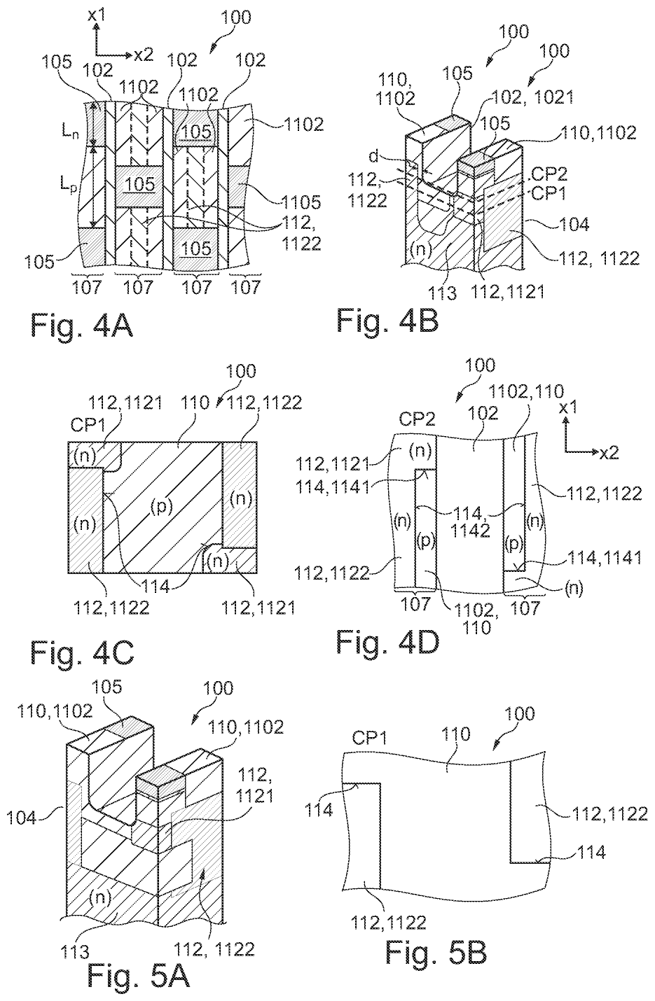

The schematic top view of FIG. 4A illustrates a part of a transistor cell array of a semiconductor device 100. The trench gate structures 102 are stripe-shaped extending in parallel along the first lateral direction x1. Mesa regions 107 are laterally confined by two neighboring trench gate structures 102. In each of the mesa regions 107, the source region 105 and the second sub-region 1102 of the semiconductor region 110 are arranged alternately along the first lateral direction x1. Source regions 105 in neighboring mesa regions 107 are arranged with an offset along the first lateral direction x1. Although the second sub-region 1122 of the current spread region 112 does not reach the surface of the SiC semiconductor body 104, the second sub-region 1122 of the current spread region 112 is shown in the plan view of FIG. 4A for illustration purposes. The second sub-region 1122 of the current spread region 112 and the trench gate structure 102 are spaced from one another along the second lateral direction x2.

The view of FIG. 4B is an exemplary schematic 3D view of the semiconductor device 100 of FIG. 4A. An illustration of the trench gate structure 102 is simplified by illustrating a gate dielectric 1021 and omitting a gate electrode. The trench gate structure 102 and the second sub-region 1122 of the current spread region 112 are spaced from one another by a lateral distance d, and the second sub-region 1102 of the semiconductor region 110 is arranged between trench gate structure 102 and the second sub-region 1122 of the current spread region 112. The second sub-region 1102 of the semiconductor region 110 adjoins a bottom side of the trench gate structure 102. The n-doped current spread region 112 turns into an n-doped drift region 113.

The view of FIG. 4C is a horizontal cross-section along plane CP1 of FIG. 4B. The pn junction 114 is formed between the n-doped first sub-region 1121 of the current spread region 112 and the p-doped semiconductor region 110, and between the n-doped second sub-region 1122 of the current spread region 112 and the p-doped semiconductor region 110.

The view of FIG. 4D is a horizontal cross-section along plane CP2 of FIG. 4B. The second sub-region 1102 of the semiconductor region 110 is arranged between the second sub-region 1122 of the current spread region 112 and the trench gate structure 102. A first section 1141 of the pn junction 114 is located between the first sub-region 1121 of the current spread region 112 and the second sub-region 1102 of the semiconductor region 110. The first section 114 of the pn junction 114 extends, at least partly, along the second lateral direction x2 that is perpendicular to the first lateral direction x1. A second section 1142 of the pn junction 114 is located between the second sub-region 1122 of the current spread region 112 and the second sub-region 1102 of the semiconductor region 110. The second section 1142 of the pn junction 114 extends along the first lateral direction x1, e.g. the longitudinal direction of the stripe-shaped trench gate structures 102 or mesa regions 107.

The view of FIG. 5A is another exemplary schematic 3D view of the semiconductor device 100 of FIG. 4A. The exemplary schematic 3D view of the semiconductor device 100 of FIG. 5A differs from the exemplary schematic 3D view of the semiconductor device 100 of FIG. 4B in that the second sub-region 1102 of the semiconductor region 110 in a first one of the mesa regions 107 not only adjoins a bottom side of the trench gate structure 102, but also extends into a neighboring second one of the mesa regions 107 and adjoins a bottom side of the first sub-region 1121 of the current spread region.

The view of FIG. 5B is a horizontal cross-section along plane CP1 of FIG. 5A. The pn junction 114 laterally surrounds the n-doped second sub-region 1122 of the current spread region 112.

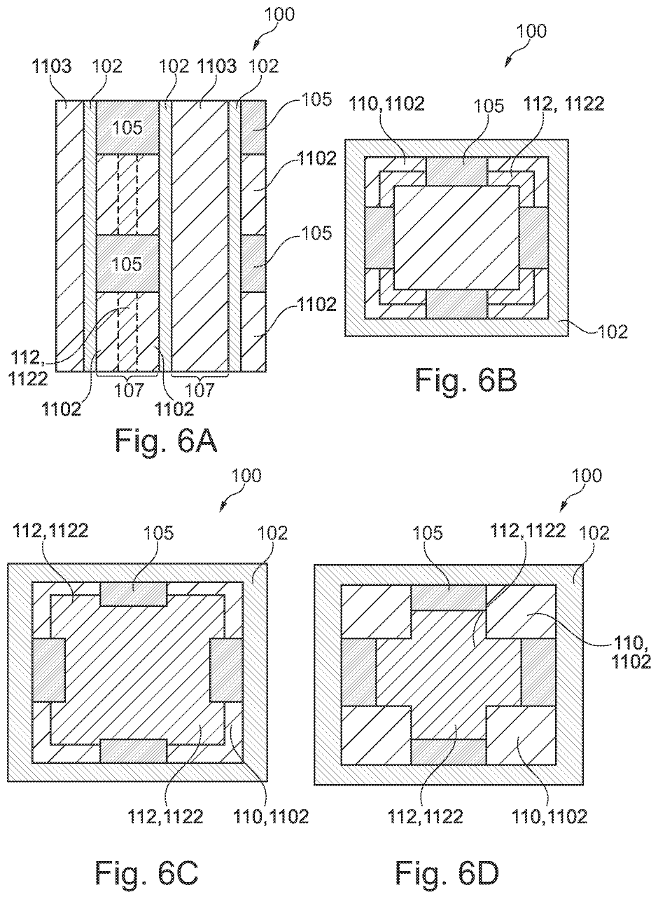

Further semiconductor devices 100 in FIGS. 6A to 6D illustrate transistor cell designs having a source region and a second sub-region 1102 of the semiconductor region 110 arranged alternately in combination with a current spread region 112. The transistor cell design in the top view of FIG. 6A differs from the design illustrated in FIG. 4A in that the source and current spread regions are omitted in every second mesa region. Apart from stripe-shaped cell layouts, other layouts such as exemplary square layouts of FIGS. 6B to 6D may be used.

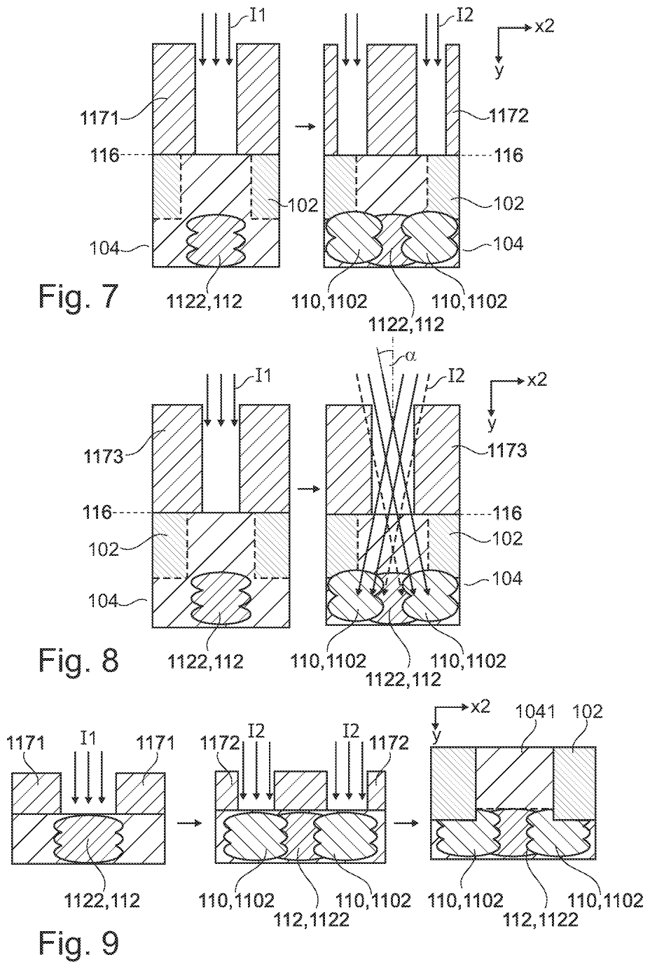

The schematic cross-sectional views of FIGS. 7 to 9 illustrate examples of forming the second sub-region 1102 of the semiconductor region 110 and the second sub-region 1122 of the current spread region 112.

Referring to the schematic cross-sectional views of FIG. 7, forming the second sub-region 1122 of the current spread region 112 includes at least one ion implantation process I1 using a first ion implantation mask 1171, e.g. a hard mask and/or a resist mask, over a processing surface, e.g. the first surface 116, and forming the second sub-region 1102 of the semiconductor region 110 includes at least one ion implantation process I2 using a second ion implantation mask 1172, e.g. a hard mask and/or a resist mask, over the processing surface that differs from the first ion implantation mask 1171.

Referring to the schematic cross-sectional views of FIG. 8, forming the second sub-region 1122 of the current spread region 112 includes at least one ion implantation process I1 using an ion implantation mask 1173, e.g. a hard mask and/or a resist mask. Forming the second sub-region 1102 of the semiconductor region 110 includes at least one ion implantation process I2 using the ion implantation mask 1173 for forming the second sub-region 1122 of the current spread region 112. An ion implantation tilt angle α for forming the second sub-region 1122 of the current spread region 112 is smaller than an ion implantation tilt angle for forming the second sub-region 1102 of the semiconductor region 110. In the example of FIG. 8, the ion implantation tilt angle for forming the second sub-region 1122 of the current spread region 112 is zero. Ion implantation tilt angle for forming the second sub-region 1122 of the current spread region 112 that are larger than zero may also be used. The ion implantation tilt angle α refers to a tilt angle in a plane spanned by the second lateral direction x2 and the vertical direction y.

Referring to the schematic cross-sectional views of FIG. 9, after the at least one ion implantation process I1 using the first ion implantation mask 1171, and after the at least one ion implantation process I2 using the second ion implantation mask 1172 over the processing surface, a semiconductor layer 1041 is formed over the processing surface. Forming the trench gate structure 102 includes forming a trench into or through the semiconductor layer 1041. A bottom side of the trench ends in the second sub-region 1102 of the semiconductor region 110.

The description and drawings merely illustrate the principles of the disclosure. Furthermore, all examples recited herein are principally intended expressly to be only for illustrative purposes to aid the reader in understanding the principles of the disclosure and the concepts contributed by the disclosed subject matter to furthering the art. All statements herein reciting principles, aspects, and examples of the disclosure, as well as specific examples thereof, are intended to encompass equivalents thereof. The first conductivity type may be n-type and the second conductivity type may be p-type. As an alternative, the first conductivity type may be p-type and the second conductivity type may be n-type.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that the present disclosure be limited only by the claims and the equivalents thereof.

1. A semiconductor device, comprising:
a trench gate structure in a silicon carbide (SiC) semiconductor body;
a source region of a first conductivity type that adjoins the trench gate structure in a first segment;
a semiconductor region of a second conductivity type, wherein the semiconductor region comprises a first sub-region arranged below the source region in the first segment, and a second sub-region arranged in a second segment that adjoins the first segment; and
a current spread region of the first conductivity type, wherein the current spread region comprises a first sub-region that adjoins the trench gate structure in the first segment at a vertical distance to a first surface of the SiC semiconductor body, and a second sub-region that is spaced from the trench gate structure in the second segment at the vertical distance to the first surface by a lateral distance.

2. The semiconductor device of the claim 1, wherein:
a doping concentration profile defining the current spread region changes, along a first lateral direction, from a first doping concentration level in the first segment to a second doping concentration level in the second segment; and
at least a part of the trench gate structure extends along the first lateral direction.

3. The semiconductor device of claim 1, comprising:
a pn junction between the semiconductor region and the current spread region, wherein:
a vertical distance from the pn junction to the first surface changes, along a first lateral direction, from a first vertical distance in the first segment to a second vertical distance in the second segment; and
at least a part of the trench gate structure extends along the first lateral direction.

4. The semiconductor device of claim 1, wherein a vertical concentration profile of dopants defining the first sub-region of the semiconductor region is different from a vertical concentration profile of dopants defining the second sub-region of the semiconductor region.

5. The semiconductor device of claim 1, wherein a doping concentration profile defining the current spread region alternates, along the first lateral direction, between a first doping concentration level and a second doping concentration level.

6. The semiconductor device of claim 1, comprising:
a pn junction between the semiconductor region and the current spread region, wherein a vertical distance from the pn junction to the first surface varies within the second segment.

7. A semiconductor device, comprising:
a trench gate structure in a silicon carbide (SiC) semiconductor body, wherein at least a part of the trench gate structure extends along a first lateral direction;
a source region of a first conductivity type that adjoins the trench gate structure in a first segment;
a semiconductor region of a second conductivity type, wherein the semiconductor region comprises a first sub-region arranged below the source region in the first segment, and a second sub-region arranged in a second segment that adjoins the first segment; and
a current spread region of the first conductivity type, wherein a doping concentration profile defining the current spread region changes, along the first lateral direction, from a first doping concentration level in the first segment to a second doping concentration level in the second segment.

8. The semiconductor device of claim 7, wherein the second sub-region of the semiconductor region is arranged between the current spread region and the trench gate structure.

9. The semiconductor device of claim 7, comprising:
a pn junction between the semiconductor region and the current spread region, wherein a vertical distance from the pn junction to a first surface of the SiC semiconductor body changes, along the first lateral direction, from a first vertical distance in the first segment to a second vertical distance in the second segment.

10. The semiconductor device of claim 7, wherein a vertical concentration profile of dopants defining the first sub-region of the semiconductor region is different from a vertical concentration profile of dopants defining the second sub-region of the semiconductor region.

11. The semiconductor device of claim 7, wherein the doping concentration profile defining the current spread region alternates, along the first lateral direction, between the first doping concentration level and the second doping concentration level.

12. The semiconductor device of claim 7, comprising:
a pn junction between the semiconductor region and the current spread region, wherein a vertical distance from the pn junction to a first surface of the SiC semiconductor body varies within the second segment.

13. A method of manufacturing a semiconductor device, comprising:
forming a trench gate structure in a silicon carbide (SiC) semiconductor body;
forming a source region of a first conductivity type that adjoins the trench gate structure in a first segment;
forming a semiconductor region of a second conductivity type, wherein the semiconductor region comprises a first sub-region arranged below the source region in the first segment, and a second sub-region arranged in a second segment that adjoins the first segment; and
forming a current spread region of the first conductivity type, wherein the current spread region comprises a first sub-region that adjoins the trench gate structure in the first segment at a vertical distance to a first surface, and a second sub-region that is spaced from the trench gate structure in the second segment at the vertical distance to the first surface by a lateral distance.

14. The method of claim 13, wherein:
forming the second sub-region of the current spread region comprises performing at least one ion implantation process using a first ion implantation mask over a processing surface; and
forming the second sub-region of the semiconductor region comprises performing at least one ion implantation process using a second ion implantation mask over the processing surface, wherein the second ion implantation mask is different from the first ion implantation mask.

15. The method of claim 14, comprising, after (i) performing the at least one ion implantation process using the first ion implantation mask and (ii) performing the at least one ion implantation process using the second ion implantation mask:
forming a semiconductor layer over the processing surface, wherein forming the trench gate structure comprises forming a trench at least one of into or through the semiconductor layer.

16. The method of claim 13, wherein:
forming the second sub-region of the semiconductor region comprises performing at least one first ion implantation process using an ion implantation mask; and
forming the second sub-region of the current spread region comprises performing at least one second ion implantation process using the ion implantation mask.

17. The method of claim 16, wherein an ion implantation tilt angle of the at least one first ion implantation process is different from an ion implantation tilt angle of the at least one second ion implantation process.

18. A method of manufacturing a semiconductor device, comprising:
forming a trench gate structure in a silicon carbide (SiC) semiconductor body, wherein at least a part of the trench gate structure extends along a first lateral direction;
forming a source region of a first conductivity type that adjoins the trench gate structure in a first segment;
forming a semiconductor region of a second conductivity type, wherein the semiconductor region comprises a first sub-region arranged below the source region in the first segment, and a second sub-region arranged in a second segment that adjoins the first segment along the first lateral direction; and
forming a current spread region of the first conductivity type, wherein a doping concentration profile defining the current spread region changes, along the first lateral direction, from a first doping concentration level in the first segment to a second doping concentration level in the second segment.

19. The method of claim 18, wherein:
forming the second sub-region of the semiconductor region comprises performing at least one ion implantation process using an ion implantation mask over a processing surface.

20. The method of claim 19, comprising, after performing the at least one ion implantation process using the ion implantation mask:
forming a semiconductor layer over the processing surface, wherein forming the trench gate structure comprises forming a trench at least one of into or through the semiconductor layer.
